(19) United States
(12) Patent Application Publication
(10) Pub. No.: US 2024/0219629 A1
(43) Pub. Date: Jul. 4, 2024

(54) PHOTONIC INTEGRATED CIRCUITS WITH GLASS CORES

(71) Applicant: Intel Corporation, Santa Clara, CA (US)

(72) Inventors: Changhua Liu, Chandler, AZ (US); Robert May, Chandler, AZ (US); Bai Nie, Chandler, AZ (US)

(21) Appl. No.: 18/148,945

(22) Filed: Dec. 30, 2022

(51) Int. Cl. G02B 6/12; G02B 6/13; H01L 23/538; H01L 25/00; H01L 25/18

(52) U.S. Cl. CPC G02B 6/12004; G02B 6/13; H01L 23/5385; H01L 25/18; H01L 25/50; H01L 24/16

(57) ABSTRACT

Methods, apparatus, systems, and articles of manufacture are disclosed utilizing photonic integrated circuits with glass cores. An example apparatus comprises a primary package substrate including a glass core and first contacts along an outer surface of the primary package substrate, a photonic integrated circuit (PIC) within the primary package substrate adjacent a surface of the glass core, and a secondary package substrate supporting a semiconductor die on a first side of the secondary package substrate, the secondary package substrate including second contacts on a second side of the secondary package substrate, the first contacts electrically coupled to the second contacts.

### FIELD OF THE DISCLOSURE

This disclosure relates generally to integrated circuit packages and, more particularly, to photonic integrated circuits with glass cores.

### BACKGROUND

Integrated circuit (IC) chips and/or semiconductor dies are routinely connected to larger circuit boards such as motherboards and other types of printed circuit boards (PCBs) via a package substrate. IC chips have exhibited increases in interconnect densities as technology has advanced.

### BRIEF DESCRIPTION OF THE DRAWINGS

FIG. 1 illustrates an example integrated circuit (IC) package on a printed circuit board.

FIG. 2 is a cross-sectional view of an example package substrate that may be implemented in the IC package of FIG. 1.

FIG. 3 is a cross-sectional view of an example IC package including example sub-packages.

FIG. 4 is a flowchart representative of an example method of manufacturing the example IC package of FIG. 3.

FIGS. 5-10 illustrate different stages in an example process of manufacturing the example IC package of FIG. 3.

FIG. 11 illustrates another example IC package constructed in accordance with teachings disclosed herein.

FIG. 12 illustrates yet another example IC package constructed in accordance with teachings disclosed herein.

FIG. 13 is a top view of a wafer including dies that may be included in an IC package constructed in accordance with teachings disclosed herein.

FIG. 14 is a cross-sectional side view of an IC device that may be included in an IC package constructed in accordance with teachings disclosed herein.

FIG. 15 is a cross-sectional side view of an IC device assembly that may include an IC package constructed in accordance with teachings disclosed herein.

FIG. 16 is a block diagram of an example electrical device that may include an IC package constructed in accordance with teachings disclosed herein.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Many known integrated circuit (IC) packages for silicon photonics include multiple semiconductor dies (e.g., XPU dies, logic circuit dies, electronic integrated circuit (EIC) drivers, etc.) and an optic element (e.g., photonic integrated circuit (PIC)) that couples the optic signal to external fibers. In such examples, the bandwidth requirement increases with the addition of multiple dies, power units, integrated optical elements, and/or the metal interconnects (e.g., build up layers, interconnect bridges, etc.). The electrical performance of the IC package can be degraded by the addition of such components. Previous solutions to integrate silicon photonics have utilized a glass core with an embedded PIC. In some examples, more build up layers and metal interconnects (e.g., through glass vias (TGVs)) are used with glass cores to facilitate performance of the IC package.

Examples disclosed herein utilize two electrically coupled, sub-package components for use with PICs, reducing the need for multiple dies, metal interconnects, and optical units on a single package substrate. Examples disclosed herein enable sub-packages, each having a substrate (e.g., a glass core), to support different components of the photonic circuit while maintaining functional requirements. Examples disclosed herein utilize contacts included in each of the sub-packages to electrically couple the sub-packages and maintain the functioning of the PIC. Examples disclosed herein utilize a glass core to embed a PIC. In other examples disclosed herein, a PIC is mounted on a side of a glass core.

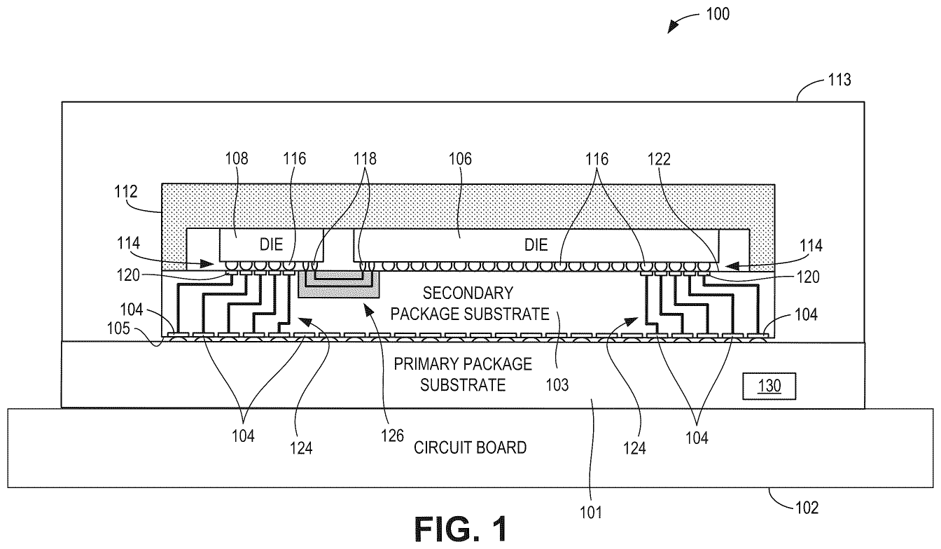

FIG. 1 illustrates an example integrated circuit (IC) package (e.g., a semiconductor package) 100 constructed in accordance with teachings disclosed herein. The example IC package 100 includes an example first or primary package substrate 101 that is electrically coupled to an example circuit board 102. Further, the example IC package 100 includes an example second or secondary package substrate 103 electrically coupled to the primary package substrate 101 via an example array of contact pads or lands 104 on a mounting surface (e.g., a bottom surface) of the package. In some examples, the IC package 100 may include balls, pins, and/or pads, in addition to or instead of the contact pads 104, to enable the electrical coupling of the secondary package substrate 103 to the primary package substrate 101 and/or to enable the electrical coupling of the primary package substrate 101 to the circuit board 102. In this example, the package 100 includes two example semiconductor (e.g., silicon) dies 106, 108 (sometimes also referred to as chips or chiplets) that are mounted to an example package substrate 110 and enclosed by an example package lid or mold compound 112. In the illustrated example of FIG. 1, the package lid 112 is enclosed by an example package housing 113. While the example IC package 100 of FIG. 1 includes two dies 106, 108, in other examples, the package 100 may have only one die or more than two dies. In some examples, one of the dies 106, 108 (or a separate die) is embedded in the secondary package substrate 103. The dies 106, 108 can provide any suitable type of functionality (e.g., data processing, memory storage, etc.).

In the illustrated example, each of the dies 106, 108 is electrically and mechanically coupled to the secondary package substrate 103 via corresponding example arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the secondary package substrate 103 (e.g., the interconnects 114) are sometimes referred to as first level interconnects. By contrast, the electrical connections between the secondary package substrate 103 and the primary package substrate 101 (e.g., the pads 104) are sometimes referred to as second level interconnects. Further, the electrical connections between the primary package substrate 101 and the circuit board 102 are sometimes referred to as third level interconnects.

In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the secondary package substrate 103 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in the example of FIG. 1, the interconnects 114 of the first level interconnects include two different types of bumps, namely, example core bumps 116 and example bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the secondary package substrate 103, the core bumps 116 are physically connected and electrically coupled to example contact pads 120 on an example inner surface 122 of the secondary package substrate 103. The contact pads 120 on the inner surface 122 of the secondary package substrate 103 are electrically coupled to the landing pads 104 on the bottom (external) surface 105 of the secondary package substrate 103 (e.g., a surface opposite the inner surface 122) via example internal interconnects 124 within the secondary package substrate 103. As a result, there is a complete signal path between the bumps 116 of the dies 106, 108 and the landing pads 104 mounted to the primary package substrate 101 and, subsequently, mounted to the circuit board 102 that pass through the contact pads 120 and the interconnects 124 provided therebetween.

As used herein, bridge bumps are bumps on the dies through which electrical signals pass between different ones of the dies within IC package. More particularly, bridge bumps differ from core bumps in that bridge bumps electrically connect two or more different dies via an interconnect bridge embedded (e.g., the example interconnect bridge 126 of FIG. 1) embedded in an underlying substrate (e.g., the package substrate 110). As represented in FIG. 1, core bumps 116 are typically larger than bridge bumps 118. In some examples, the interconnect bridge 126 and the associated bridge bumps 118 are omitted.

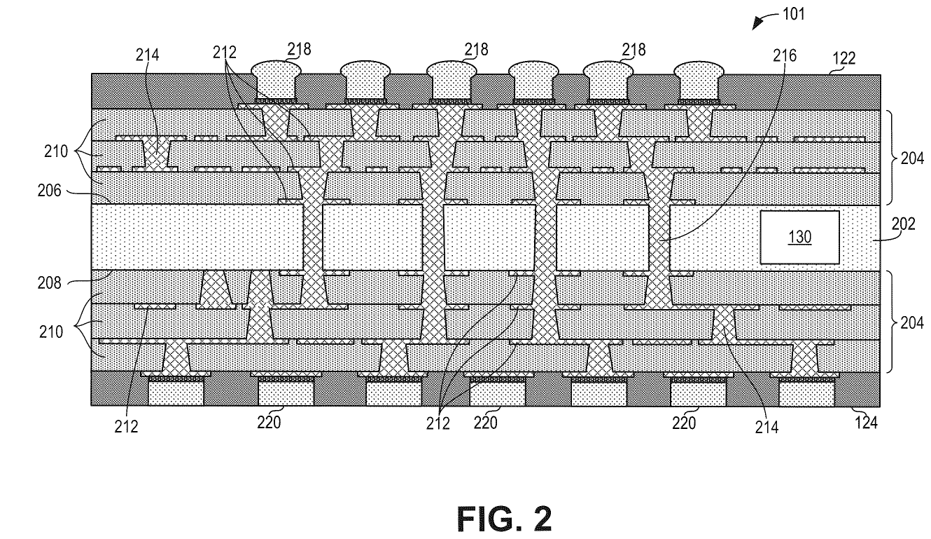

The example IC package 100 of FIG. 1 is a photonic package that includes an example optical component 130 integrated with and/or carried by the primary package substrate 101. More particularly, in some examples, the primary package substrate 101 includes an example glass substrate, layer, or core 202 (shown in FIG. 2) to which the optical component 130 is coupled. In some examples, light is directed through and/or along the glass core 202 toward the optical component 130. In some examples, the optical component 130 is distinct from the dies 106, 108 coupled to and/or carried by the secondary package substrate 103. In some such examples, at least one of the dies 106, 108 is a photonic integrated circuit (PIC) that is optically coupled to the optical component 130 supported by the primary package substrate 101. Additionally or alternatively, at least one of the dies 106, 108 may be electrically coupled to electrodes of the optical component 130. In some examples, the IC package 100 includes more than one optical component 130.

FIG. 2 is a cross-sectional view providing further detail for an example implementation of the example primary package substrate 101 of FIG. 1. The primary package substrate 101 of the illustrated example includes a glass substrate or core 202 between two separate example build-up layers or regions 204. In this example, the build-up regions 204 are provided on an example first surface 206 of the glass core 202 and an example second surface 208 of the glass core 202 opposite the first surface 206. The build-up regions 204 of the illustrated example are defined by an alternating pattern of insulation of example dielectric layers 210 and example patterned conductive (e.g., metal) layers 212. In this example, there are three dielectric layers 210 and three conductive layers 212 in the build-up regions 204 (not including the outermost layer of conductive material). However, in other examples, any other suitable number of dielectric and conductive layers 210, 212 may be employed. In some examples, the build-up region 204 on at least one side of the glass core 202 may be omitted such that the glass core defines an exterior surface of the primary package substrate 101.

The conductive layers 212 in the build-up regions 204 are patterned to define electrical routing or conductive traces that serve as signaling or transmission lines to transfer power and/or signals of information between two or more components (e.g., transistors, capacitors, resistors, backend layers, etc. and/or other circuitry) of an associated IC package (e.g., the IC package 100 of FIG. 1). Example electrically conductive (e.g., metal) vias 214 extend through the dielectric layers 210 to electrically coupled different ones of the conductive layers 212 in the different build-up regions 204. Further, as shown in FIG. 2, the glass core 202 of the illustrated example includes one or more example through glass vias (TGVs) 216 (e.g., copper plated vias) that extend between the opposite surfaces 206, 208 of the glass core 202 to communicatively and/or electrically couple the conductive layers 212 and associated metal vias 214 within the build-up regions 204 on either side of the glass core 202. Thus, in this examples, the electrical routing or traces defined by the patterning of the conductive layers 212, the conductive vias 214, and the TGVs 216 collectively define electrical interconnects (e.g., the interconnects 126 of FIG. 1) through the primary package substrate 101.

In the illustrated example, the primary package substrate 101 includes a first plurality of example connectors 218 (e.g., solder balls, bumps, contact pads, pins, etc.) on the inner surface 122 of the primary package substrate 101 to electrically couple the primary package substrate 101 to another package substrate (e.g., the secondary package substrate 103 of FIG. 1) and/or any other suitable component (e.g., an interposer). Further, the example primary package substrate 101 includes a second plurality of example solder connectors 220 (e.g., solder balls, bumps, contact pads, pins, etc.) to electrically couple the primary package substrate 101 to a printed circuit board (e.g., the circuit board 102 of FIG. 1), an interposer and/or any other substrate(s).

Although the glass core 202 of the example primary package substrate 101 is shown as a central core of the primary package substrate 101, in some examples, the glass core 202 can be an interposer and/or any other layer of the primary package substrate 101. For example, the glass core 202 can be used in place of one or more of the dielectric layers 210 of the primary package substrate 101. In some examples, the primary package substrate 101 can include different material(s) including organic materials, silicon, and/or other conventional materials for fabricating package substrates. In some examples, the primary package substrate 101 includes an embedded multi-die interconnect bridge (EMIB) (e.g., the bridge 126 of FIG. 1).

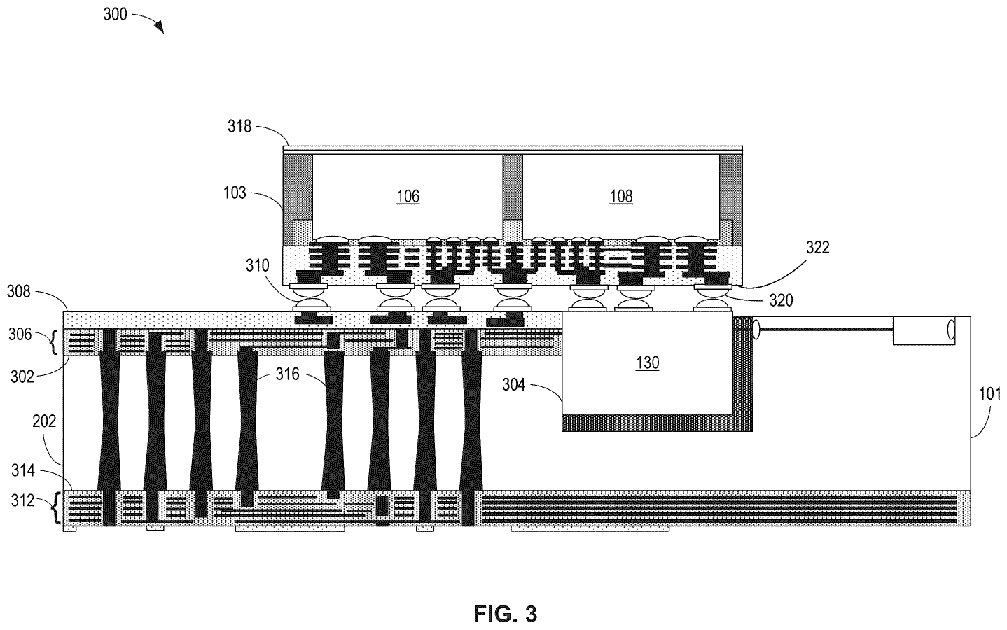

Using glass (e.g., the glass core 202 of FIG. 2) as a starting core material has a mechanical benefit, an electrical benefit, and a design flexibility benefit over using traditional organic core materials (e.g., epoxy-based prepreg). Furthermore, glass cores can be used as waveguides to define optical signal paths capable of transmitting light. As a result, it is possible to incorporate or integrate optical components directly into a package substrate adjacent a surface of the glass core. More particularly, in the illustrated example, of FIG. 2, the optical component 130 is on the first surface 206 of the glass core 202. In other examples, the optical component 130 may be on the second surface 208 of the glass core 202. In other examples, the optical component 130 may embedded within a cavity in the glass core 202. In the illustrated example, the optical component 130 has a height or thickness that is greater than one dielectric layer 210 but less than the thickness of two dielectric layers 210. However, in other examples, the optical component 130 can be larger or smaller than shown (e.g., equal to or less than the thickness of one dielectric layer 210, equal to or greater than two dielectric layers 210, etc.). Example constructions of optical components within substrate containing a glass core are further detailed in FIGS. 3-13.

FIG. 3 illustrates an example IC package 300 constructed in accordance with teachings disclosed herein. The example IC package 300 of FIG. 3 is an example implementation of the IC package 100 of FIG. 1. Accordingly, the same reference numbers used in FIGS. 1 and 2 are used for similar components in FIG. 3. The example IC package 300 of FIG. 3 includes the primary package substrate 101 having the glass core 202 and the optical component 130 (e.g., a PIC). In some examples, the example optical component 130 can be positioned adjacent to an example first side 302 (e.g., surface) of the glass core 202. In other examples, the optical component 130 can be embedded in an example cavity 304 in the glass core 202.

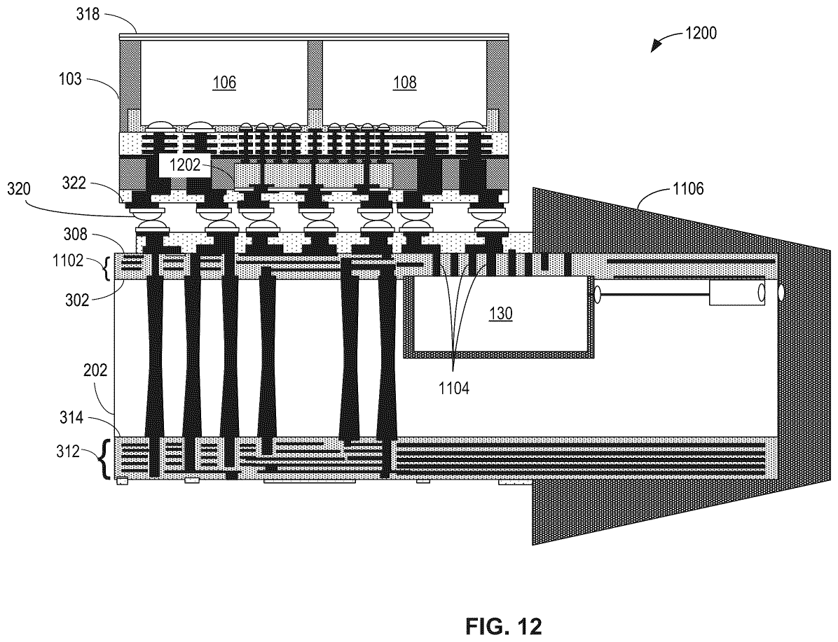

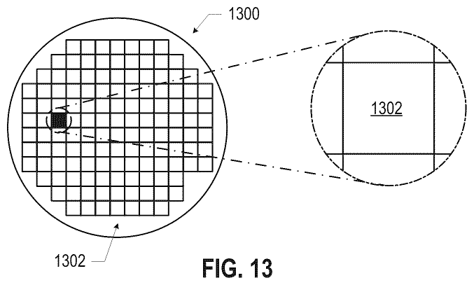

As shown in the example of FIG. 3, the primary package substrate 101 includes an example build-up region 306 between the glass core 202 and an example outer surface 308 of the primary package substrate 101. Further, the example primary package substrate 101 includes example first contacts 310 (e.g., solder interconnects) along the outer surface 308. The example build-up region 306 includes electrical routing positioned between the glass core 202 and a first subset of the first contacts 310. The example optical component 130 is electrically coupled to a second subset of the first contacts 310, independent of the electrical routing in the build-up region 306. In other examples, the build-up region 306 extends over the optical component 130, as described in detail in connection with FIGS. 12 and 13.

In the example of FIG. 3, an example build-up region 312 is provided on an example second side 314 of the glass core 202, the second side 314 opposite the first side 302. As such, the glass core 202 is positioned between the build-up region 306 and the build-up region 312. The example glass core 202 includes at least one example through glass via (TGV) 316 extending through the glass core 202 to electrically couple the build-up region 306 and the build-up region 312. In particular, the example TGVs 316 electrically couple the electrical routing included in the build-up region 306 to the electrical routing included in the build-up region 312. Further, the at least one of the TGVs 316 is electrically coupled to at least one of the first contacts 310 through the electrical routing.

Further, the example IC package 300 includes the secondary package substrate 103. In some examples, the secondary package substrate 103 supports at least one of the die 106 or the die 108 on an example first side 318 of the secondary package substrate 103. However, as shown in the example of FIG. 3, the secondary package substrate 103 can support both of the dies 106, 108 on the first side 318. In other words, the example dies 106, 108 can be mounted on the first side 318. The secondary package substrate 103 further includes example second contacts 320 on an example second side 322 of the secondary package substrate 103. In some examples, the second side 322 is opposite the first side 318.

The second contacts 320 electrically couple to the first contacts 310 of the primary package substrate 101 with solder. In other words, the secondary package substrate 103 is attached to the outer surface 308 (e.g., side) of the primary package substrate 101 via the contacts 310, 320 extending between the package substrates 101, 103. As such, the primary package substrate 101 is electrically coupled to the secondary package substrate 103 via the first and second contacts 310, 320. In this example, the optical component 130 is a first distance away from the second side 322 of the secondary package substrate 103 and the build-up region 306 is a second distance away from the second side 322, the first distance less than or equal to the second distance.

The example dies 106, 108 are electrically coupled to the optical component 130 via the first and second contacts 310, 320. In some examples, the die 106 is a logic circuit die that is electrically coupled to the optical component 130 via the first and second contacts 310, 320. Further, the die 108 can be an electronic integrated circuit (EIC) driver that is electrically coupled to the optical component 130 via the first and second contacts 310, 320. In the example of FIG. 3, the die 106 is electrically coupled to the die 106 through (e.g., via electrical routing) the secondary package substrate 103. As such, each of the dies 106, 108 can be electrically coupled to the optical component 130.

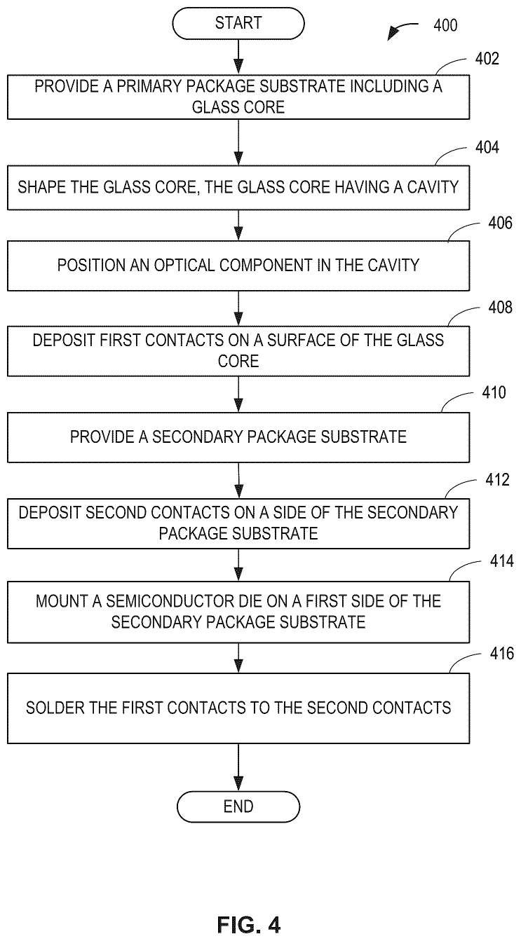

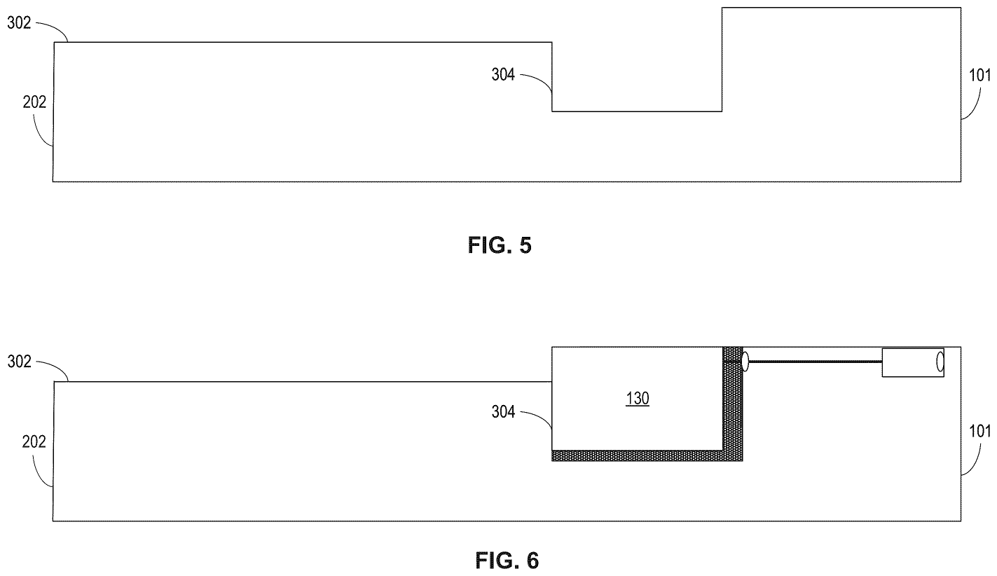

FIG. 4 is a flowchart representative of example methods to produce the example IC package 300 of FIG. 3. FIGS. 5-10 represent the example IC package 300 at various stages during the process described in FIG. 4.

Turning to FIG. 4, the example process 400 begins at block 402 at which the primary package substrate 101 is provided, the primary package substrate 101 including the glass core 202. At block 404, the glass core 202 is shaped to include the cavity 304. As shown in FIG. 5, the glass core 202 includes the cavity 304 in the first side 302 of the glass core 202. In some examples, the glass core 202 can be shaped by multiple pieces of glass core subsequently bonded together.

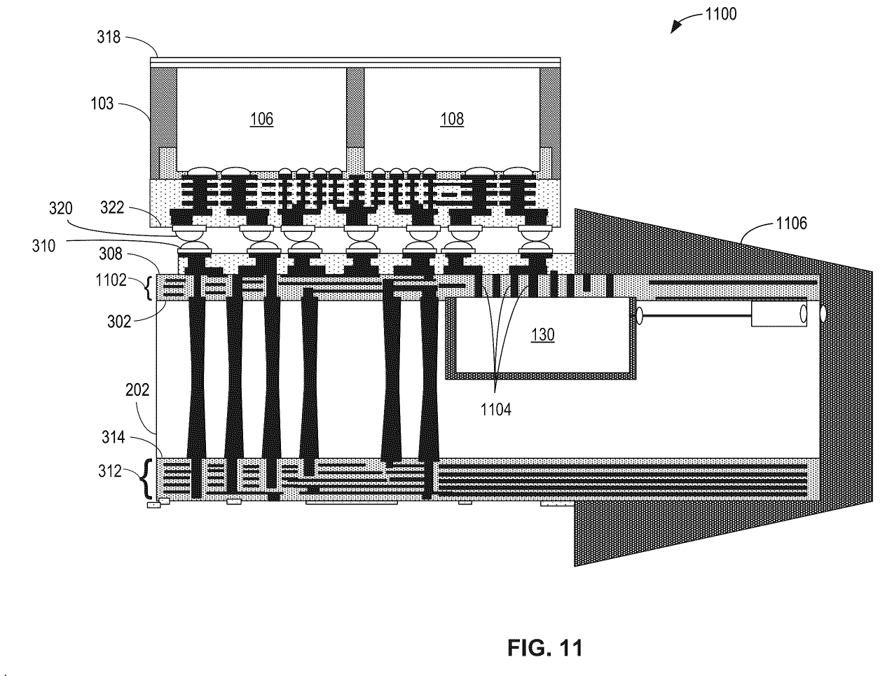

At block 406, the optical component 130 is positioned in the cavity 304, as shown in FIG. 6. In the example of FIG. 6, the optical component 130 is adjacent to the side 302. However, in the example of FIGS. 11 and 12, the optical component 130 can be embedded in the glass core 202. In some other examples, the optical component 130 can be positioned in a first one of multiple pieces of glass core, with subsequent ones of the multiple pieces bonded together to produce the assembly shown in FIG. 6.

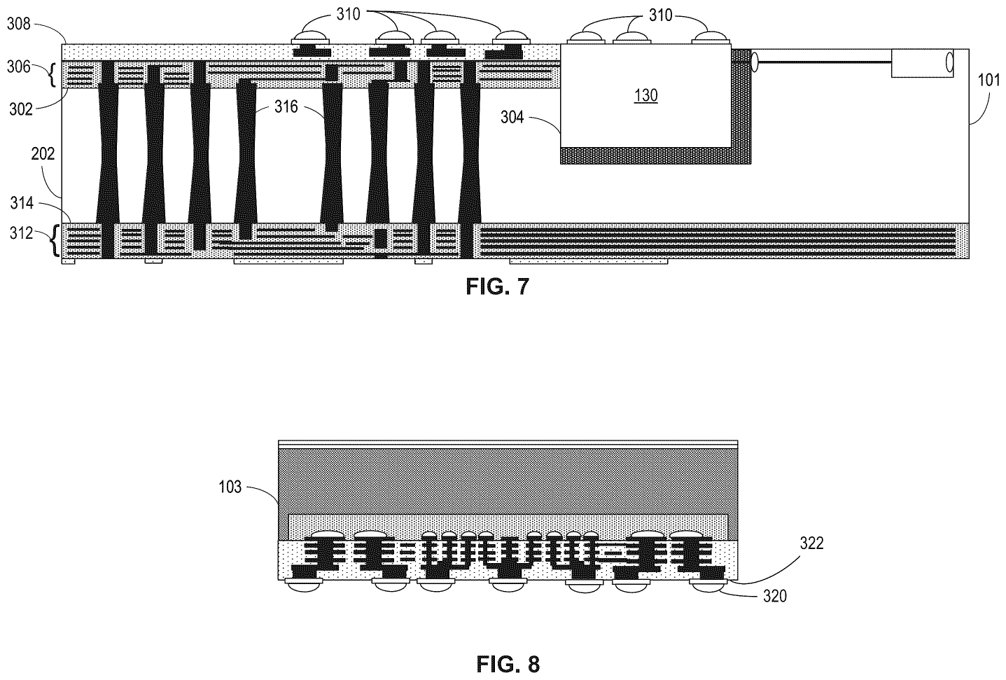

At block 408, the first contacts 310 are deposited on the side 302 of the glass core 202. As shown in FIG. 7, the first contacts 310 are electrically coupled to the build-up region 306 and to the optical component 130. Further, the glass core 202 can be shaped to include the TGVs 316 extending through the glass core 202 from the first side 302 to the second side 314. The example TGVs electrically couple the build-up region 312 on the second side 314 to the build-up region 306 on the first side 302 and, subsequently, the first contacts 310. In some examples, the build-up region 306 extends over (e.g., covers) the optical component 130, as shown in the examples of FIGS. 11 and 12.

At block 410, the secondary package substrate 103 is provided. At block 412, the second contacts 320 are deposited on the side 322 of the secondary package substrate 103. As shown in FIG. 8, the second contacts 320 are electrically coupled to electrical routing on the side 322 of the secondary package substrate 103.

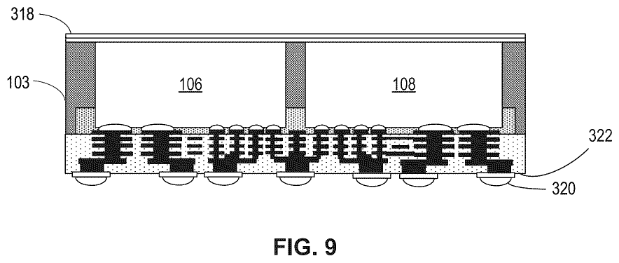

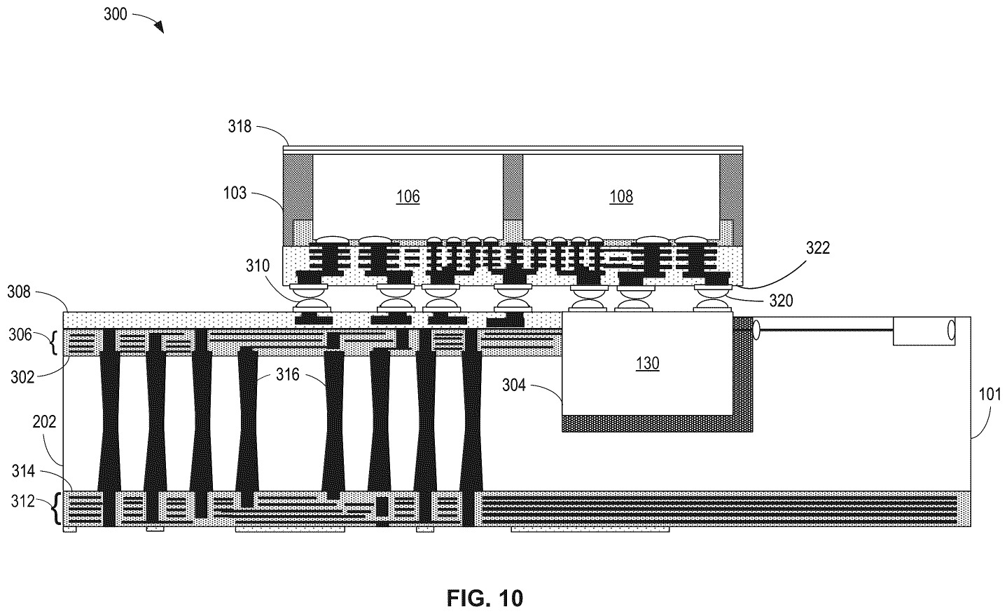

At block 414, a semiconductor die is mounted (e.g., positioned, attached, etc.) on the side 322 of the secondary package substrate 103. As shown in FIG. 9, the semiconductor dies 106, 108 are both attached to the side 318 of the secondary package substrate 103. In other examples, at least one of the dies 106, 108 are attached to the side 318 of the secondary package substrate 103. In the example of FIG. 9, the dies 106, 108 are electrically coupled via electrical routing on the side 322. In other examples, the dies 106, 108 are electrically coupled via an interconnect bridge 1202, as shown in FIG. 12. In some examples, the die 106 is a logic circuit die and the die 108 is an EIC driver.

At block 416, the first contacts 310 are soldered to the second contacts 320, as shown in FIG. 10. Thus, the primary package substrate 101 is electrically coupled to the secondary package substrate 103 via the coupled first and second contacts 310, 320. Accordingly, the optical component 130 is electrically coupled to at least one of the dies 106, 108 the coupled first and second contacts 310, 320. In other examples, other techniques can be used in addition or as an alternative to soldering to mechanically and electrically couple the first and second contacts 310, 320.

FIG. 11 is another example IC package 1100 constructed in accordance with teachings disclosed herein. FIG. 11 is similar to example IC package 300 of FIG. 3, but instead, the example IC package 1100 includes an example build-up region 1102 extending over the optical component 130. The example build-up region 1102 is positioned between the first contacts 310 and the optical component 130. As such, the example build-up region 1102 includes example electrical routing 1104 to electrically couple the optical component 130 to the first contacts 310. In the example of FIG. 11, the optical component 130 is electrically coupled to the dies 106, 108 via the electrical routing 1104 in the build-up region 1102 and the coupled first and second contacts 310, 320. Moreover, the example IC package 1100 includes an example clamp 1106. In some examples, the clamp 1106 secures the IC package 1100. In some examples, the IC package 1100 does not include the clamp 1106.

FIG. 12 is another example IC package 1200 constructed in accordance with teachings disclosed herein. The example IC package 1200 of FIG. 12 is similar to example IC package 1100 of FIG. 11, but instead, the example IC package 1200 includes an example interconnect bridge 1202 embedded (e.g., positioned) in the secondary package substrate 103. In the example of FIG. 12, the interconnect bridge 1202 electrically couples the die 106 to the die 108. As such, the example optical component 130 is electrically coupled to the dies 106, 108 via the interconnect bridge 1202, the electrical routing 1104 in the build-up region 1102, and the coupled first and second contacts 310, 320.

The example IC packages 300, 1100, 1200 disclosed herein may be included in any suitable electronic component. FIGS. 13-16 illustrate various examples of apparatus that may include or be included in the IC packages 300, 1100, 1200 disclosed herein.

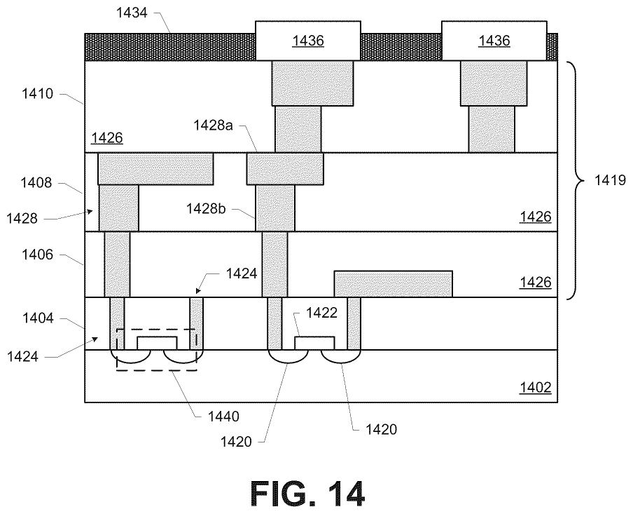

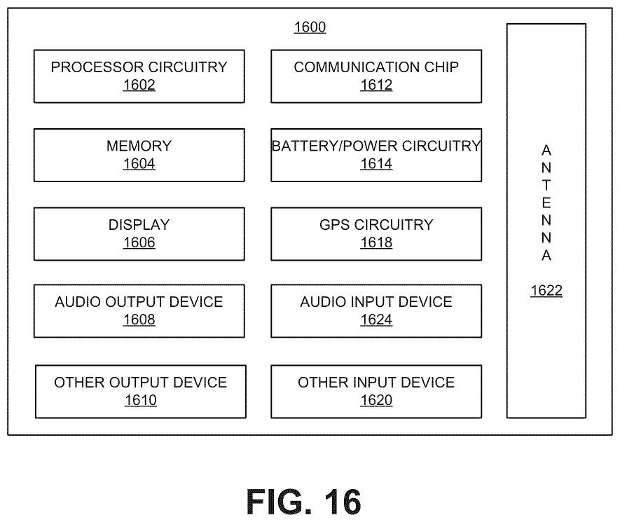

FIG. 13 is a top view of an example wafer 1300 and dies 1302 that may be included in the IC packages 300, 1100, 1200 (e.g., as any suitable ones of the dies 106, 108 and/or the optical component 130). The wafer 1300 may be composed of semiconductor material and may include one or more dies 1302 having circuitry. Some or all of the dies 1302 may be a repeating unit of a semiconductor product. After the fabrication of the semiconductor product is complete, the wafer 1300 may undergo a singulation process in which the dies 1302 are separated from one another to provide discrete “chips.” The die 1302 may include one or more transistors (e.g., some of the transistors 1440 of FIG. 14, discussed below), supporting circuitry to route electrical signals to the transistors, passive components (e.g., traces, resistors, capacitors, inductors, and/or other circuitry), and/or any other components. In some examples, the die 1302 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1302. For example, a memory array formed by multiple memory circuits may be formed on a same die 1302 as programmable circuitry (e.g., the processor circuitry 1602 of FIG. 16) or other logic circuitry. Such memory may store information for use by the programmable circuitry. The example IC packages 300, 1100, 1200 disclosed herein may be manufactured using a die-to-wafer assembly technique in which some dies 106, 108 are attached to a wafer 1300 that include others of the dies 106, 108, and the wafer 1300 is subsequently singulated.

FIG. 14 is a cross-sectional side view of an example IC device 1400 that may be included in the example IC packages 300, 1100, 1200 (e.g., in any one of the dies 106, 108). One or more of the IC devices 1400 may be included in one or more dies 1302 (FIG. 13). The IC device 1400 may be formed on an example die substrate 1402 (e.g., the wafer 1300 of FIG. 13) and may be included in a die (e.g., the die 1302 of FIG. 13). The die substrate 1402 may be a semiconductor substrate composed of semiconductor material systems including, for example, n-type or p-type materials systems (or a combination of both). The die substrate 1402 may include, for example, a crystalline substrate formed using a bulk silicon or a silicon-on-insulator (SOI) substructure. In some examples, the die substrate 1402 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an IC device 1400 may be used. The die substrate 1402 may be part of a singulated die (e.g., the dies 1302 of FIG. 13) or a wafer (e.g., the wafer 1300 of FIG. 13).

The IC device 1400 may include one or more example device layers 1404 disposed on or above the die substrate 1402. The device layer 1404 may include features of one or more example transistors 1440 (e.g., metal oxide semiconductor field-effect transistors (MOSFETs)) formed on the die substrate 1402. The device layer 1404 may include, for example, one or more example source and/or drain (S/D) regions 1420, an example gate 1422 to control current flow between the S/D regions 1420, and one or more example S/D contacts 1424 to route electrical signals to/from the S/D regions 1420. The transistors 1440 may include additional features not depicted for the sake of clarity such as, for example, device isolation regions, gate contacts, and the like. The transistors 1440 are not limited to the type and configuration depicted in FIG. 14 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1440 may include an example gate 1422 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1440 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as for example a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1440 along the source-channel-drain direction, the gate electrode may include a U-shaped structure that includes a bottom portion substantially parallel to the surface of the die substrate 1402 and two sidewall portions that are substantially perpendicular to the top surface of the die substrate 1402. In other examples, at least one of the metal layers that form the gate electrode may be a planar layer that is substantially parallel to the top surface of the die substrate 1402 and does not include sidewall portions substantially perpendicular to the top surface of the die substrate 1402. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of respective ones of the transistors 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes the dopants to diffuse farther into the die substrate 1402 may follow the ion-implantation process. In the latter process, the die substrate 1402 may first be etched to form recesses at the locations of the S/D regions 1420. An epitaxial deposition process may then be carried out to fill the recesses with material that is used to fabricate the S/D regions 1420. In some implementations, the S/D regions 1420 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1420 may be formed using one or more alternate semiconductor materials such as germanium or a group III-V material or alloy. In further examples, one or more layers of metal and/or metal alloys may be used to form the S/D regions 1420.

Electrical signals, such as power and/or input/output (I/O) signals, may be routed to and/or from the devices (e.g., transistors 1440) of the device layer 1404 through one or more example interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with example interconnect structures 1428 of the interconnect layers 1406-1410. The one or more interconnect layers 1406-1410 may form an example metallization stack (also referred to as an “ILD stack”) 1419 of the IC device 1400.

The interconnect structures 1428 may be arranged within the interconnect layers 1406-1410 to route electrical signals according to a wide variety of designs (in particular, the arrangement is not limited to the particular configuration of interconnect structures 1428 depicted in FIG. 14). Although a particular number of interconnect layers 1406-1410 is depicted in FIG. 14, examples of the present disclosure include IC devices having more or fewer interconnect layers than depicted.

In some examples, the interconnect structures 1428 may include example lines 1428a and/or example vias 1428b filled with an electrically conductive material such as a metal. The lines 1428a may be arranged to route electrical signals in a direction of a plane that is substantially parallel with a surface of the die substrate 1402 upon which the device layer 1404 is formed. For example, the lines 1428a may route electrical signals in a direction in and out of the page from the perspective of FIG. 14. The vias 1428b may be arranged to route electrical signals in a direction of a plane that is substantially perpendicular to the surface of the die substrate 1402 upon which the device layer 1404 is formed. In some examples, the vias 1428b may electrically couple lines 1428a of different interconnect layers 1406-1410 together.

The interconnect layers 1406-1410 may include an example dielectric material 1426 disposed between the interconnect structures 1428, as shown in FIG. 14. In some examples, the dielectric material 1426 disposed between the interconnect structures 1428 in different ones of the interconnect layers 1406-1410 may have different compositions. In other examples, the composition of the dielectric material 1426 between different interconnect layers 1406-1410 may be the same.

A first interconnect layer 1406 (referred to as Metal 1 or “M1”) may be formed directly on the device layer 1404. In some examples, the first interconnect layer 1406 may include lines 1428a and/or vias 1428b, as shown. The lines 1428a of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some examples, the second interconnect layer 1408 may include vias 1428b to couple the lines 1428a of the second interconnect layer 1408 with the lines 1428a of the first interconnect layer 1406. Although the lines 1428a and the vias 1428b are structurally delineated with a line within each interconnect layer (e.g., within the second interconnect layer 1408) for the sake of clarity, the lines 1428a and the vias 1428b may be structurally and/or materially contiguous (e.g., simultaneously filled during a dual-damascene process) in some examples.

A third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 and/or the first interconnect layer 1406. In some examples, the interconnect layers that are “higher up” in the metallization stack 1419 in the IC device 1400 (i.e., further away from the device layer 1404) may be thicker.

The IC device 1400 may include an example solder resist material 1434 (e.g., polyimide or similar material) and one or more example conductive contacts 1436 formed on the interconnect layers 1406-1410. In FIG. 14, the conductive contacts 1436 are illustrated as taking the form of bond pads. The conductive contacts 1436 may be electrically coupled with the interconnect structures 1428 and configured to route the electrical signals of the transistor(s) 1440 to other external devices. For example, solder bonds may be formed on the one or more conductive contacts 1436 to mechanically and/or electrically couple a chip including the IC device 1400 with another component (e.g., a circuit board). The IC device 1400 may include additional or alternate structures to route the electrical signals from the interconnect layers 1406-1410; for example, the conductive contacts 1436 may include other analogous features (e.g., posts) that route the electrical signals to external components.

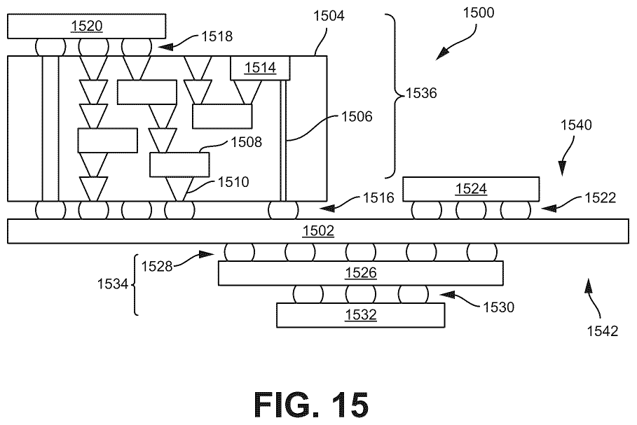

FIG. 15 is a cross-sectional side view of an example IC device assembly 1500 that may include the IC packages 300, 1100, 1200 disclosed herein. In some examples, the IC device assembly corresponds to the IC packages 300, 1100, 1200. The IC device assembly 1500 includes a number of components disposed on an example circuit board 1502 (which may be, for example, a motherboard). The IC device assembly 1500 includes components disposed on an example first face 1540 of the circuit board 1502 and an example opposing second face 1542 of the circuit board 1502. Any of the IC packages discussed herein with reference to the IC device assembly 1500 may take the form of the example IC packages 300, 1100, 1200.

In some examples, the circuit board 1502 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other examples, the circuit board 1502 may be a non-PCB substrate. In some examples, the circuit board 1502 may be, for example, the circuit board 102 of FIG. 1.

The IC device assembly 1500 illustrated in FIG. 15 includes an example package-on-interposer structure 1536 coupled to the first face 1540 of the circuit board 1502 by example coupling components 1516. The coupling components 1516 may electrically and mechanically couple the package-on-interposer structure 1536 to the circuit board 1502, and may include solder balls (as shown in FIG. 15), male and female portions of a socket, an adhesive, an underfill material, and/or any other suitable electrical, chemical, and/or mechanical coupling structure.

The package-on-interposer structure 1536 may include an example IC package 1520 coupled to an example interposer 1504 by example coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504. Additionally or alternatively, in some examples, additional interposers may be coupled to the interposer 1504. The interposer 1504 may provide an intervening substrate used to bridge the circuit board 1502 and the IC package 1520. The IC package 1520 may be or include, for example, a die (the die 1302 of FIG. 13), an IC device (e.g., the IC device 1400 of FIG. 14), and/or any other suitable component(s). Generally, the interposer 1504 may spread a connection to a wider pitch or reroute a connection to a different connection. For example, the interposer 1504 may couple the IC package 1520 (e.g., a die) to a set of BGA conductive contacts of the coupling components 1516 for coupling to the circuit board 1502. In the example illustrated in FIG. 15, the IC package 1520 and the circuit board 1502 are attached to opposing sides of the interposer 1504. In other examples, the IC package 1520 and the circuit board 1502 may be attached to a same side of the interposer 1504. In some examples, three or more components may be interconnected by way of the interposer 1504.

In some examples, the interposer 1504 may be formed as a PCB, including multiple metal layers separated from one another by layers of dielectric material and interconnected by electrically conductive vias. In some examples, the interposer 1504 may be formed of an epoxy resin, a fiberglass-reinforced epoxy resin, an epoxy resin with inorganic fillers, a ceramic material, or a polymer material such as polyimide. In some examples, the interposer 1504 may be formed of alternate rigid or flexible materials that may include the same materials described above for use in a semiconductor substrate, such as silicon, germanium, and other group III-V and group IV materials. The interposer 1504 may include example metal interconnects 1508 and example vias 1510, including but not limited to example through-silicon vias (TSVs) 1506. The interposer 1504 may further include example embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an example IC package 1524 coupled to the first face 1540 of the circuit board 1502 by example coupling components 1522. The coupling components 1522 may take the form of any of the examples discussed above with reference to the coupling components 1516, and the IC package 1524 may take the form of any of the examples discussed above with reference to the IC package 1520.

The IC device assembly 1500 illustrated in FIG. 15 includes an example package-on-package structure 1534 coupled to the second face 1542 of the circuit board 1502 by coupling components 1528. The package-on-package structure 1534 may include a first example IC package 1526 and a second example IC package 1532 coupled together by example coupling components 1530 such that the first IC package 1526 is disposed between the circuit board 1502 and the second IC package 1532. The coupling components 1528, 1530 may take the form of any of the examples of the coupling components 1516 discussed above, and the IC packages 1526, 1532 may take the form of any of the examples of the IC package 1520 discussed above.

FIG. 16 is a block diagram of an example electrical device 1600 that may include one or more of the example IC packages 300, 1100, 1200. For example, any suitable ones of the components of the electrical device 1600 may include one or more of the device assemblies 1500, IC devices 1400, or dies 1302 disclosed herein, and may be arranged in the example IC packages 300, 1100, 1200. A number of components are illustrated in FIG. 16 as included in the electrical device 1600, but any one or more of these components may be omitted or duplicated, as suitable for the application. In some examples, some or all of the components included in the electrical device 1600 may be attached to one or more motherboards. In some examples, some or all of these components are fabricated onto a single system-on-a-chip (SoC) die.

Additionally, in some examples, the electrical device 1600 may not include one or more of the components illustrated in FIG. 16, but the electrical device 1600 may include interface circuitry for coupling to the one or more components. For example, the electrical device 1600 may not include an example display 1606, but may include display interface circuitry (e.g., a connector and driver circuitry) to which the display 1606 may be coupled. In some examples, the electrical device 1600 may not include an example audio input device 1624 (e.g., microphone) or an example audio output device 1608 (e.g., a speaker, a headset, earbuds, etc.), but may include audio input or output device interface circuitry (e.g., connectors and supporting circuitry) to which the audio input device 1624 or the audio output device 1608 may be coupled.

The electrical device 1600 may include example programmable or processor circuitry 1602 (e.g., one or more processing devices). The processor circuitry 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1600 may include an example memory 1604, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1604 may include memory that shares a die with the programmable circuitry 1602. This memory may be used as cache memory and may include embedded dynamic random access memory (eDRAM) or spin transfer torque magnetic random access memory (STT-MRAM).

In some examples, the electrical device 1600 may include an example communication chip 1612 (e.g., one or more communication chips). For example, the communication chip 1612 may be configured for managing wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1612 may operate in accordance with other wireless protocols in other examples. The electrical device 1600 may include an example antenna 1622 to facilitate wireless communications and/or to receive other wireless communications (such as AM or FM radio transmissions).

In some examples, the communication chip 1612 may manage wired communications, such as electrical, optical, or any other suitable communication protocols (e.g., the Ethernet). As noted above, the communication chip 1612 may include multiple communication chips. For instance, a first communication chip 1612 may be dedicated to shorter-range wireless communications such as Wi-Fi or Bluetooth, and a second communication chip 1612 may be dedicated to longer-range wireless communications such as global positioning system (GPS), EDGE, GPRS, CDMA, WiMAX, LTE, EV-DO, or others. In some examples, a first communication chip 1612 may be dedicated to wireless communications, and a second communication chip 1612 may be dedicated to wired communications.

The electrical device 1600 may include example battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include the display 1606 (or corresponding interface circuitry, as discussed above). The display 1606 may include any visual indicators, such as a heads-up display, a computer monitor, a projector, a touchscreen display, a liquid crystal display (LCD), a light-emitting diode display, or a flat panel display.

The electrical device 1600 may include the audio output device 1608 (or corresponding interface circuitry, as discussed above). The audio output device 1608 may include any device that generates an audible indicator, such as speakers, headsets, or earbuds.

The electrical device 1600 may include the audio input device 1624 (or corresponding interface circuitry, as discussed above). The audio input device 1624 may include any device that generates a signal representative of a sound, such as microphones, microphone arrays, or digital instruments (e.g., instruments having a musical instrument digital interface (MIDI) output).

The electrical device 1600 may include example GPS circuitry 1618. The GPS circuitry 1618 may be in communication with a satellite-based system and may receive a location of the electrical device 1600, as known in the art.

The electrical device 1600 may include any other example output device 1610 (or corresponding interface circuitry, as discussed above). Examples of the other output device 1610 may include an audio codec, a video codec, a printer, a wired or wireless transmitter for providing information to other devices, and/or an additional storage device.

The electrical device 1600 may include any other example input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1600 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1600 may be any other electronic device that processes data.

From the foregoing, it will be appreciated that example systems, methods, apparatus, and articles of manufacture have been disclosed that enable sub-packages, each having a substrate (e.g., a glass core), to support different components of the photonic circuit while maintaining functional requirements. Examples disclosed herein utilize contacts included in each of the sub-packages to electrically couple the sub-package and maintain the functioning of the PIC. Examples disclosed herein utilize a glass core to embed a PIC.

Further examples and combinations thereof include the following:
Example 1 includes an apparatus, comprising a primary package substrate including a glass core and first contacts along an outer surface of the primary package substrate, a photonic integrated circuit (PIC) within the primary package substrate adjacent a surface of the glass core, and a secondary package substrate supporting a semiconductor die on a first side of the secondary package substrate, the secondary package substrate including second contacts on a second side of the secondary package substrate, the first contacts electrically coupled to the second contacts.
Example 2 includes the apparatus of example 1, wherein the semiconductor die is a logic circuit die, the logic circuit die electrically coupled to the PIC via the coupled first and second contacts.
Example 3 includes the apparatus of examples 1 or 2, wherein the logic circuit die is electrically coupled to an electronic integrated circuit (EIC) driver through the secondary package substrate, the secondary package substrate supporting the EIC driver on the first side of the secondary package substrate, the EIC driver electrically coupled to the PIC via the coupled first and second contacts.
Example 4 includes the apparatus of example 3, further including an interconnect bridge embedded in the secondary package substrate, the logic circuit die and the EIC driver electrically coupled via the interconnect bridge.
Example 5 includes the apparatus of any of examples 1-4, wherein the primary package substrate includes a build-up region between the glass core and the outer surface, the build-up region including electrical routing, the build-up region between the glass core and a first subset of the first contacts, a second subset of the first contacts electrically coupled to the PIC independent of the electrical routing in the build-up region.
Example 6 includes the apparatus of example 5, wherein the build-up region is a first build-up region and the electrical routing is first electrical routing, the primary package including a second build-up region including second electrical routing, the glass core between the first and second build-up regions, the glass core including a through glass via (TGV) extending through the glass core to electrically couple the second electrical routing to the first electrical routing, the first electrical routing electrically coupled to the first subset of the first contacts.
Example 7 includes the apparatus of any of examples 1-6, wherein the PIC is embedded in a cavity in the glass core, the primary package substrate including a build-up region containing electrical routing, the build-up region positioned between the first contacts and the PIC, the electrical routing to electrically couple the PIC to the first contacts.
Example 8 includes an integrated circuit (IC) package, comprising a first package substrate having a first side and a second side opposite the first side, a semiconductor die mounted on the first side of the first package substrate, a second package substrate attached to the second side the first package substrate by solder interconnects extending between the first and second package substrates, the second package substrate including a glass core, and a photonic integrated circuit (PIC) within the second package substrate adjacent the glass core, the semiconductor die electrically coupled to the PIC through the solder interconnects.
Example 9 includes the IC package of example 8, wherein the semiconductor die is a first semiconductor die, the IC package further including a second semiconductor die mounted on the first side of the first package substrate.
Example 10 includes the IC package of example 9, wherein the first semiconductor die is an electronic integrated circuit (EIC) driver and the second semiconductor die is a logic circuit die.
Example 11 includes the IC package of examples 9 or 10, wherein the first semiconductor die is electrically coupled to the second semiconductor die through the first package substrate.
Example 12 includes the IC package of example 11, wherein the first semiconductor die is electrically coupled to the second semiconductor die via an interconnect bridge, the interconnect bridge positioned within the first package substrate.
Example 13 includes the IC package of any of examples 8-12, wherein the second package substrate includes a build-up region and a through glass via (TGV), the build-up region between the glass core and the second side of the glass core, the TGV to extend through the glass core, the build-up region including electrical routing to electrically couple the TGV to ones of the solder interconnects.
Example 14 includes the IC package of example 13, wherein the build-up region is positioned between the PIC and the second side of the first package substrate, the PIC electrically coupled to the semiconductor die via the electrical routing.
Example 15 includes the IC package of example 14, wherein the PIC is a first distance away from the second side of the first package substrate, and the build-up region is a second distance away from the second side of the first package substrate, the first distance less than or equal to the second distance.
Example 16 includes a method of manufacturing an integrated circuit (IC) package, the method comprising providing a primary package substrate, the primary package substrate including a glass core, positioning a photonic integrated circuit (PIC) adjacent a surface of the glass core, providing first contacts on a first side of the glass core, providing a secondary package substrate and a semiconductor die supported by the secondary package substrate on a first side of the secondary package substrate, a second side of the secondary package substrate including second contacts, soldering the first contacts to the second contacts.
Example 17 includes the method of example 16, wherein the semiconductor die is a logic circuit die, the logic circuit die electrically coupled to the PIC via the first and second contacts.
Example 18 includes the method of example 17, wherein the providing of the sub-package includes attaching the logic circuit die to the first side of the secondary package substrate, and attaching an electronic integrated circuit (EIC) driver to the first side of the secondary package substrate adjacent the logic circuit die, the EIC driver electrically coupled to the PIC via the coupled first and second contacts.
Example 19 includes the method of example 18, further including embedding an interconnect bridge in the secondary package substrate, the interconnect bridge to electrically couple the EIC driver and the logic circuit die.
Example 20 includes the method of any of examples 16-19, further including embedding the PIC in a cavity of the glass core, and providing a build-up layer that covers the PIC, the PIC electrically coupled to the semiconductor die via electrical routing in the build-up layer.
Example 21 includes the method of example 20, further including electrically coupling the PIC to the second contacts without a build-up region disposed therebetween.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus, comprising:
a primary package substrate including a glass core and first contacts along an outer surface of the primary package substrate;
a photonic integrated circuit (PIC) within the primary package substrate adjacent a surface of the glass core; and
a secondary package substrate supporting a semiconductor die on a first side of the secondary package substrate, the secondary package substrate including second contacts on a second side of the secondary package substrate, the first contacts electrically coupled to the second contacts.

2. The apparatus of claim 1, wherein the semiconductor die is a logic circuit die, the logic circuit die electrically coupled to the PIC via the coupled first and second contacts.

3. The apparatus of claim 2, wherein the logic circuit die is electrically coupled to an electronic integrated circuit (EIC) driver through the secondary package substrate, the secondary package substrate supporting the EIC driver on the first side of the secondary package substrate, the EIC driver electrically coupled to the PIC via the coupled first and second contacts.

4. The apparatus of claim 3, further including an interconnect bridge embedded in the secondary package substrate, the logic circuit die and the EIC driver electrically coupled via the interconnect bridge.

5. The apparatus of claim 1, wherein the primary package substrate includes a build-up region between the glass core and the outer surface, the build-up region including electrical routing, the build-up region between the glass core and a first subset of the first contacts, a second subset of the first contacts electrically coupled to the PIC independent of the electrical routing in the build-up region.

6. The apparatus of claim 5, wherein the build-up region is a first build-up region and the electrical routing is first electrical routing, the primary package including a second build-up region including second electrical routing, the glass core between the first and second build-up regions, the glass core including a through glass via (TGV) extending through the glass core to electrically couple the second electrical routing to the first electrical routing, the first electrical routing electrically coupled to the first subset of the first contacts.

7. The apparatus of claim 1, wherein the PIC is embedded in a cavity in the glass core, the primary package substrate including a build-up region containing electrical routing, the build-up region positioned between the first contacts and the PIC, the electrical routing to electrically couple the PIC to the first contacts.

8. An integrated circuit (IC) package, comprising:
a first package substrate having a first side and a second side opposite the first side;
a semiconductor die mounted on the first side of the first package substrate;
a second package substrate attached to the second side the first package substrate by solder interconnects extending between the first and second package substrates, the second package substrate including a glass core; and
a photonic integrated circuit (PIC) within the second package substrate adjacent the glass core, the semiconductor die electrically coupled to the PIC through the solder interconnects.

9. The IC package of claim 8, wherein the semiconductor die is a first semiconductor die, the IC package further including a second semiconductor die mounted on the first side of the first package substrate.

10. The IC package of claim 9, wherein the first semiconductor die is an electronic integrated circuit (EIC) driver and the second semiconductor die is a logic circuit die.

11. The IC package of claim 9, wherein the first semiconductor die is electrically coupled to the second semiconductor die through the first package substrate.

12. The IC package of claim 11, wherein the first semiconductor die is electrically coupled to the second semiconductor die via an interconnect bridge, the interconnect bridge positioned within the first package substrate.

13. The IC package of claim 8, wherein the second package substrate includes a build-up region and a through glass via (TGV), the build-up region between the glass core and the second side of the glass core, the TGV to extend through the glass core, the build-up region including electrical routing to electrically couple the TGV to ones of the solder interconnects.

14. The IC package of claim 13, wherein the build-up region is positioned between the PIC and the second side of the first package substrate, the PIC electrically coupled to the semiconductor die via the electrical routing.

15. The IC package of claim 14, wherein the PIC is a first distance away from the second side of the first package substrate, and the build-up region is a second distance away from the second side of the first package substrate, the first distance less than or equal to the second distance.

16. A method of manufacturing an integrated circuit (IC) package, the method comprising:
providing a primary package substrate, the primary package substrate including a glass core;
positioning a photonic integrated circuit (PIC) adjacent a surface of the glass core;
providing first contacts on a first side of the glass core;
providing a secondary package substrate and a semiconductor die supported by the secondary package substrate on a first side of the secondary package substrate, a second side of the secondary package substrate including second contacts;
soldering the first contacts to the second contacts.

17. The method of claim 16, wherein the semiconductor die is a logic circuit die, the logic circuit die electrically coupled to the PIC via the first and second contacts.

18. The method of claim 17, wherein the providing of the sub-package includes:
attaching the logic circuit die to the first side of the secondary package substrate; and
attaching an electronic integrated circuit (EIC) driver to the first side of the secondary package substrate adjacent the logic circuit die, the EIC driver electrically coupled to the PIC via the coupled first and second contacts.

19. The method of claim 18, further including embedding an interconnect bridge in the secondary package substrate, the interconnect bridge to electrically couple the EIC driver and the logic circuit die.

20. The method of claim 16, further including:
embedding the PIC in a cavity of the glass core; and
providing a build-up layer that covers the PIC, the PIC electrically coupled to the semiconductor die via electrical routing in the build-up layer.

21. The method of claim 20, further including electrically coupling the PIC to the second contacts without a build-up region disposed therebetween.
